(19) United States
(12) Patent Application Publication
(10) Pub. No.: US 2008/0213981 A1
(43) Pub. Date: Sep. 4, 2008

(54) Method of Fabricating a Silicon-On-Insulator Structure

(75) Inventors: Philippe Renaud, Tournefeuille (FR); Isabelle Bertrand, Toulouse (FR)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: Freescale Semiconductor, Inc., Austin, TX (US)

(21) Appl. No.: 11/815,176

(22) PCT Filed: Jan. 31, 2005
(86) PCT No.: PCT/IB2005/000446

§ 371 Date: Apr. 3, 2008

(51) Int. Cl. H01L 21/20

(52) U.S. Cl. 438/479; 257/E21.09

(57) ABSTRACT

In the field of sensor fabrication, it is known to form a silicon-on-insulator starting structure from which fabrication of the sensor based. The present invention provides a method of forming a silicon-on-insulator structure comprising a substrate having an insulating layer patterned thereon. A silicon oxide layer is then deposited over the patterned insulating layer before silicon is grown over both an exposed surface of the substrate as well as the silicon oxide layer, mono-crystalline silicon forming on the exposed parts of the substrate and polysilicon forming on the silicon oxide layer. After depositing a capping layer over the structure, the wafer is heated, whereby the polysilicon re-crystallises to form mono-crystalline silicon, resulting in the insulating layer being buried beneath mono-crystalline silicon.

### FIELD OF THE INVENTION

This invention relates to, in general, a method of fabricating a silicon-on-insulator structure of the type, for example, used in the fabrication of sensors, such as acceleration sensors.

### BACKGROUND OF THE INVENTION

In the field of sensor fabrication, for example silicon acceleration sensors, a Silicon-On-Insulator (SOI) wafer is typically required as an initial structure. However, such initial structures need to be patterned prior to addition of an epitaxial layer, resulting in the SOI wafer being costly.

Several known techniques exist for forming SOI wafers. For example, U.S. Pat. No. 5,493,470 discloses a diaphragm pressure sensor formed by use of a so-called Zone Melting Re-crystallisation (ZMR) silicon-on-insulator technology, where re-crystallised silicon is used to form a diaphragm. U.S. Pat. No. 6,232,140 relates to a capacitive acceleration sensor formed in a monocrystalline SOI wafer, the monocrystalline SOI wafer comprising two bonded silicon wafers having an air gap therebetween due to the presence of a patterned oxide layer. U.S. Pat. No. 6,029,517 discloses a miniaturised accelerometer of the type having spring compensation for gravitational effects, an SOI wafer being used as a starting material. U.S. Pat. No. 6,130,464 relates to a surface micro-machined micro-accelerometer including a cantilever formed on a substrate and having a fixed end and a free end, the fixed end being anchored to the substrate; an SOI wafer (formed using one of the: BESOI, SmartCut or SIMOX fabrication techniques) is the starting material. U.S. Pat. No. 6,294,400 discloses a precision micro-mechanical semiconductor accelerometer of the differential-capacitor type comprising a pair of etched opposing cover layers fusion bonded to opposite sides of an etched proof mass layer to form an hermetically sealed assembly. WO-A-03 069355 relates to fabrication of a low-cost breakable inertial threshold acceleration sensor mainly using micro-machining silicon technology. The sensor is of the capacitive type and made of commercially available SOI wafers. U.S. Pat. No. 5,747,353 discloses a surface micro-machined accelerometer using an SOI wafer structure.

However, the above described SOI wafers are either complex to form or require specialised substrates as a starting material for the fabrication of the SOI wafer. Consequently, the cost per device is relatively high.

### STATEMENT OF INVENTION

According to the present invention, there is provided a method of fabricating a silicon-on-insulator structure as set forth in the claims herein.

### BRIEF DESCRIPTION OF THE DRAWINGS

At least one embodiment of the invention will now be described, by way of example only, with reference to the accompanying drawings, in which:

FIGS. 1A to 1G are schematic diagrams of processing steps constituting a first embodiment of the invention;

FIG. 2 is a flow diagram of a method of forming a patterned Silicon-On-Insulator wafer;

FIG. 3 is a scanning electron micrograph image of silicon grown over an insulator pattern prior to a re-crystallisation step;

FIG. 4 is a schematic diagram of an insulator structure constituting a second embodiment of the invention;

FIG. 5 is a schematic diagram of another insulating structure constituting a third embodiment of the invention;

FIGS. 6A & 6B are schematic diagrams of a first alignment arrangement for use with any of the above wafer embodiments;

FIG. 7 is a schematic diagram of a second alignment structure for use with any of the above wafer embodiment; and

FIG. 8 is a scanning electron micrograph image of an alignment pattern of FIG. 7.

### DESCRIPTION OF PREFERRED EMBODIMENTS

Throughout the following description, identical reference numerals will be used to identify like parts.

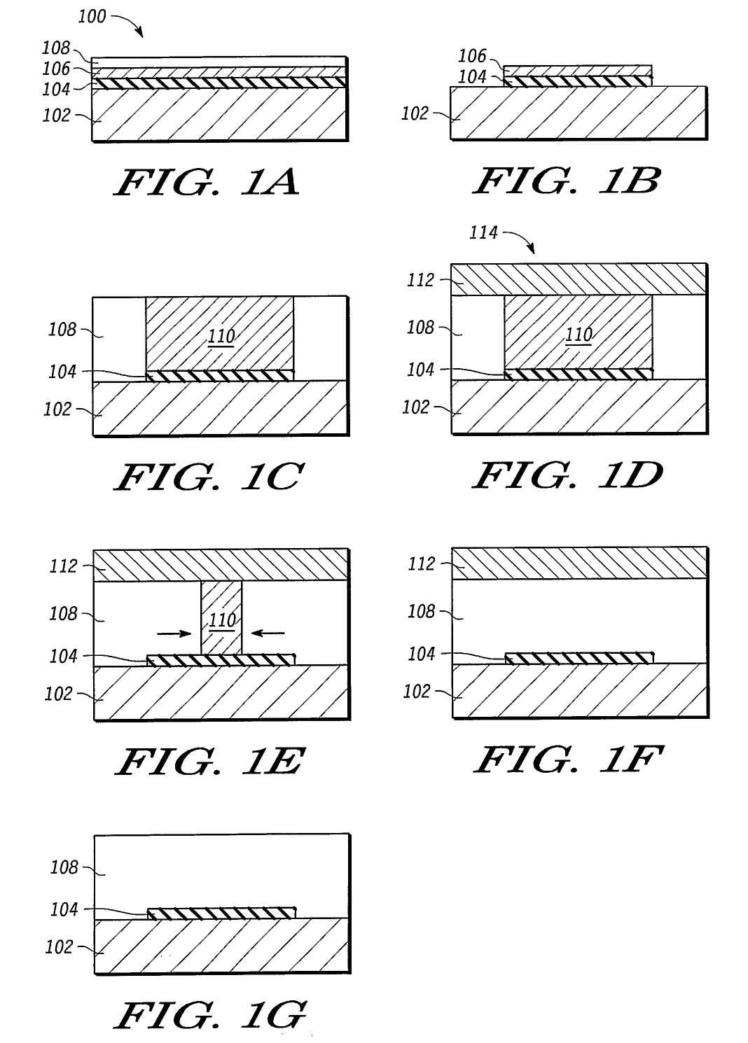

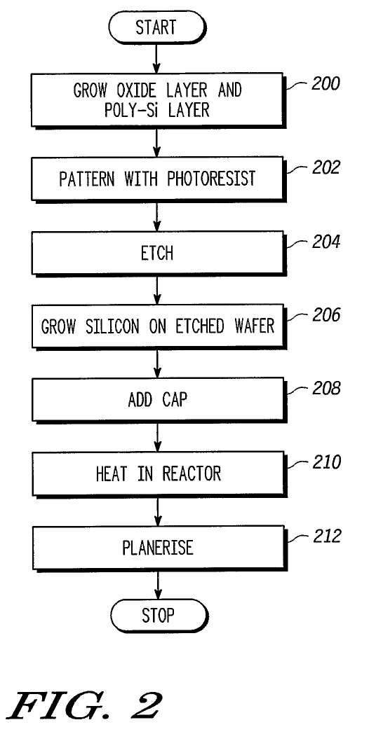

Referring to FIGS. 1(A) and 2, an initial wafer structure 100 is obtained (Step 200) by depositing an insulating layer 104, for example, a dielectric layer, such as silicon dioxide, silicon nitride, diamond film, or tantalum nitride over a monocrystalline silicon substrate 102. If the insulating layer is an oxide, the oxide can be a thermal oxide or a Low Pressure Chemical Vapour Deposition (LPCVD) oxide. The monocrystalline silicon substrate 102 is any suitable silicon substrate, in this example, for the formation of a sensor. A polysilicon (Poly-Si) seed layer 106 is then grown over the insulating layer 104 and an exposed surface of the Poly-Si seed layer 106 patterned (Step 202) using a layer of photoresist 108.

Turning to FIG. 1(B), the Poly-Si seed layer 106 is then etched (Step 204) by subjecting the initial wafer structure 100 to a Reactive Ion Etching (RIE) process. Subsequently, the insulating material 104 is etched (Step 204) using a wet etching process, for example one employing a hydrofluoric acid (HF) buffer to expose a hitherto covered surface of the silicon substrate 102. However, it is possible to achieve a similar result using the RIE process described above. In this respect, it should be appreciated that the remaining parts of the insulating layer 104 and the Poly-Si seed layer 106 are still considered “layers”.

Thereafter (FIG. 1(C)), the etched wafer is placed in an Epitaxial (EPI) reactor (not shown), for example a Chemical Vapour Deposition (CVD) Epitaxial reactor, and silicon is grown (Step 206) over the exposed surface of the silicon substrate 102 and the Poly-Si seed layer 106 to a thickness of about 30 μm. However, it should be appreciated that epitaxial growth takes place in the form of a monocrystalline silicon layer 108 forming over the exposed surface of the silicon substrate 102, whereas a polysilicon layer 110 forms in the EPI reactor over the surface of the Poly-Si seed layer 106 due to the polycrystalline structure of the Poly-Si seed layer 106. The thickness of the silicon grown can vary depending upon the dimensional requirements of the sensor ultimately being manufactured. Therefore, the overgrown silicon can be at least about 10 μm thick, for example between about 10 μm and about 60 μm, such as between about 20 μm and about 50 μm.

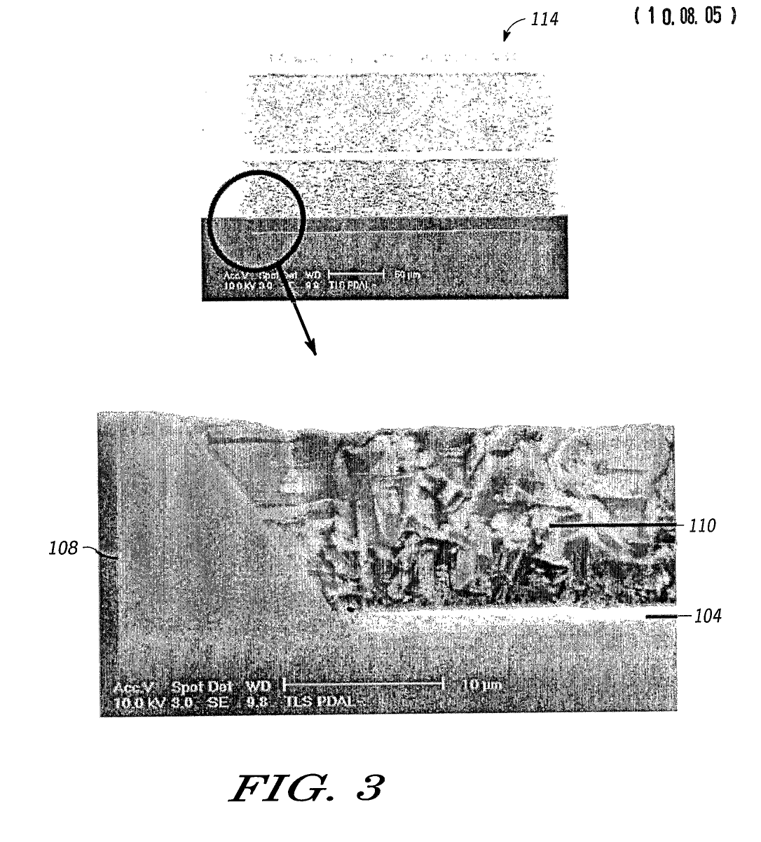

Referring to FIG. 1(D), a capping layer 112, for example a silicon dioxide layer (SiO₂), is grown (Step 208) over the overgrown monocrystalline silicon and polysilicon 108, 110 to form a capped wafer 114 that prevents evaporation of the silicon into a chamber of the furnace and consequent damage thereto; the resulting structure formed can be partially seen from FIG. 3.

The capped wafer 114 is then placed (Step 210) in a Rapid Thermal Processing (RTP) furnace (not shown) for a predetermined period of time. In the furnace, the capped wafer 114 is subjected to, in this example, a temperature of 1410° C. in order to cause the overgrown polysilicon to re-crystallises into monocrystalline silicon; the monocrystalline silicon formed over the previously exposed surface of the substrate 102 acts as a seed for the re-crystallising polysilicon as the temperature in the furnace ramps-down. The predetermined period of time is set so that all of the overgrown polysilicon is heated so as to completely re-crystallise into monocrystalline silicon.

The capped wafer 114 is then removed from the furnace and the capping layer 114 is removed by a wet-etching technique. Thereafter, the uncapped wafer is subjected to a Chemical Micro-Polishing (CMP) process in order to planarise (Step 212) the wafer, thereby removing about 3 μm of the surface of the monocrystalline silicon 108, leaving a wafer having a smooth upper surface and comprising the insulating material 104 buried beneath a layer of the monocrystalline silicon 108. The resulting silicon-on-insulator wafer is particularly suitable as a starting wafer for the production of a sensor, for example an acceleration sensor.

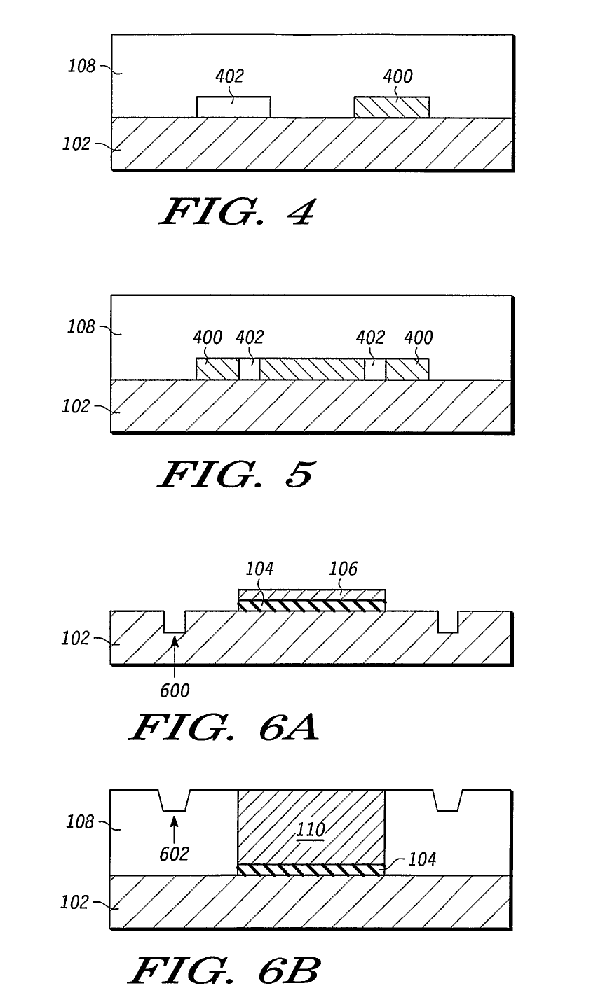

In another embodiment (FIG. 4), the insulating layer 104 is formed from a deposition of a first insulating material 400, for example a thermal oxide, such as silicon dioxide (SiO₂) and a deposition of a second insulating material 402, for example a nitride, such as silicon nitride. Each of the first and second insulating materials are respectively formed by patterning a first region with the first insulating material and patterning a second region with the second insulating material. In this example, the first region of the first insulating material 400 is spaced apart from the second region of the second insulating material 402. In such situations, it is desirable to provide a spacing of at least about 1 μm between the first and second regions, for example at least about 20 μm.

However, in a further embodiment (FIG. 5), the region of the first insulating material 400 is disposed adjacent the second region of the second insulating material 402. Indeed, in this example, the first region of the first insulating material 400 surrounds the second region of the second insulating material 402.

Referring to FIG. 6A, in order to provide one or more points of reference for the purpose of alignment, one or more alignment recesses 600 are created by etching one or more recesses into the silicon substrate 102 using any suitable known etching technique. When the monocrystalline silicon layer 108 is subsequently grown (Step 206) on the substrate 102 (FIG. 6B) as described above, one or more corresponding recesses 602 are formed in the monocrystalline silicon layer 108 by virtue of the variation in level of, in this example, the exposed surface of the silicon substrate 102.

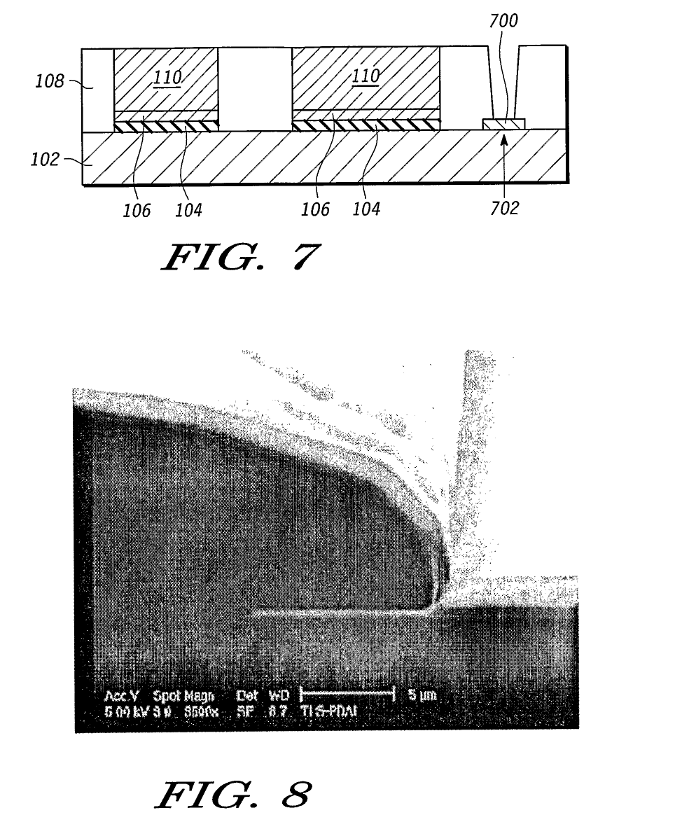

Alternatively or additionally (FIG. 7), one or more further regions 700 of the insulating material are deposited, but not covered with the Poly-Si seed layer 106, thereby substantially preventing subsequent growth of silicon on the one or more further regions 700 at the silicon overgrowth stage (Step 206). Consequently, one or more recesses 702 form in the overgrown silicon, even after the re-crystallisation stage (Step 210), as can be seen in FIG. 8. It should be appreciated that this technique for forming the one or more further regions 700 can be applied to other structures where an insulator disposed upon a substrate is overgrown with a polycrystalline semiconductor material. This technique is particularly useful where a monocrystalline semiconductor material is formed by a process of lateral epitaxial growth.

Even after the CMP stage described above, the one or more recesses 600, 702 described in the above two embodiments remain to a depth of at least 0.3 μm.

It is thus possible to provide a Silicon-On-Oxide wafer produced using a so-called Lateral Epitaxial Growth over Oxide (LEGO) fabrication technique that therefore requires fewer process steps than existing processes for fabricating a silicon-on-oxide wafer. Further, the processing technique uses a standard bulk silicon substrate as raw material, thereby reducing production costs. Additionally, since the dielectric material used as the insulating material need not necessarily be oxide, and/or indeed insulating materials can be deposited together on the same silicon substrate and/or patterned, greater design flexibility is afforded. The provision of an alignment region facilitates accurate fabrication of sensor devices.

Although specific examples of insulators have been set forth herein, it should be appreciated that any suitable insulating material can be employed that can withstand the temperature of the re-crystallisation stage.

Whilst specific, and preferred, implementations of the present invention are described above, it is clear that one skilled in the art could readily apply variations and modifications of such inventive concepts.

1. A method of fabricating a silicon-on-insulator structure for a sensor, the method being characterised by the steps of:
providing a substrate;
forming a polysilicon seed layer on an insulating material layer, the insulating material layer being formed on the substrate and arranged with the polysilicon seed layer so as to leave a substantially peripheral surface region of the substrate not covered by the insulating material layer and the polysilicon seed layer;
growing silicon over the polysilicon seed layer and the surface region of the substrate not covered by the insulating material, thereby forming a region of monocrystalline silicon and a region of polysilicon;
heating the region of monocrystalline silicon and the region of polysilicon so as to cause the region of polysilicon to re-crystallise into monocrystalline silicon.

2. A method as claimed claim 1, wherein the region of monocrystalline silicon is formed over the region of the substrate not covered by the insulating material, and the region of polysilicon is formed over the polysilicon seed layer, respectively.

3. A method as claimed in claim 1, wherein the step of forming the insulating material layer adjacent the substrate comprises the step of: patterning the substrate with a first insulating material.

4. A method as claimed in claim 3, further comprising the step of:
patterning the substrate with a second insulating material.

5. A method as claimed in claim 4, wherein a portion of the second insulating material pattern is disposed adjacent a portion of the first insulating material pattern.

6. A method as claimed in claim 5, wherein the portion of the second insulating material is substantially surrounded by the portion of the first insulating material.

7. A method as claimed in claim 3, wherein the first insulating material is a dielectric and/or the second insulating material is a dielectric.

8. A method as claimed in claim 3, wherein the first insulting material is an oxide.

9. A method as claimed in claim 4, wherein the second insulating material is a nitride.

10. A method as claimed in claim 8, wherein the oxide is silicon oxide.

11. A method as claimed in claim 9, wherein the nitride is silicon nitride or tantalum nitride.

12. A method as claimed in claim 1, further comprising the step of:
depositing a capping layer adjacent the overgrown silicon prior to heating the overgrown silicon.

13. A method as claimed in claim 1, wherein the step of growing the silicon comprises:
growing the silicon to a thickness of at least 10 μm.

14. A method as claimed in claim 1, further comprising the step of forming a recess in the substrate prior to the selective deposition of the insulating material for facilitating alignment.

15. A method as claimed in claim 2, wherein the step of depositing the polysilicon seed layer comprises the step of:
omitting deposition of a region of the polysilicon seed layer adjacent the insulating material layer so as to inhibit subsequent growth of polysilicon thereon, thereby subsequently resulting in formation of an alignment recess.

16. A method of forming an alignment recess in a structure to comprise an insulating material layer disposed beneath a moncrystalline semiconductor material by lateral epitaxial growth of the monocrystalline semiconductor material, the method comprising the step of:
omitting deposition of a region of a seed layer adjacent the insulating material layer so as to inhibit subsequent growth of polycrystalline semiconductor material thereon prior to re-crystallisation of the polycrystalline semiconductor material, thereby subsequently resulting in formation of the alignment recess in the monocrystalline semiconductor material.
